(19) United States
(12) Patent Application Publication
(10) Pub. No.: US 2005/0217824 A1
(43) Pub. Date: Oct. 6, 2005

(54) Cooling element for an electronic device

(76) Inventors: Per Sandberg, Zimmermansgatan 12 (SE); Tommy Larsson, Amanningevagen (SE); Liangyou Tang, Cumberland Place, TN (US)

Correspondence Address: MORGAN & FINNEGAN, L.L.P., 3 WORLD FINANCIAL CENTER, NEW YORK, NY, 10281-2101, US

(21) Appl. No.: 10/514,368

(22) PCT Filed: May 28, 2003
(86) PCT No.: PCT/FI03/00415

§ 371 Date: Apr. 27, 2005

(30) Foreign Application Priority Data
May 31, 2002 (FI) 20021027

(51) Int. Cl. H05K 7/20

(52) U.S. Cl. 165/80.3; 361/697

(57) ABSTRACT

The invention relates to a cooling element to be used as a heat sink for an electronic device (1, 11, 21, 31), as a microprocessor, which contains a base member (2, 12, 22, 32) attached in one side to the electronic device (1, 11, 21, 31) and in other side providing separate members for distribution (3, 17, 23, 33) of heat and for supporting a fan (6, 15, 25, 35) installed in a cavity in the middle of members for distribution (3, 17, 23, 33) and creating airflow for heat transfer. According to the invention at least one fin member (4, 18, 28, 38) is installed in space between of two adjacent distribution members (3, 17, 23, 33).

This invention relates to a cooling element to be used in cooling of an electronic device, as a microprocessor which cooling element has separately a heat distribution area and a heat transfer area.

Microprocessors of today with millions of transistors and working at high clock rates, generates a lot of heat. Most of that heat has to be removed and that is done with devices called heat sinks. Heat sinks are generally used to transfer heat away from an electronic device in order to prevent overheating of the electronic device, which may result in instantaneous or premature failure of the device. In the past, heat sinks are mainly important for power devices, such as power amplifiers, rectifiers or other power electronic devices, and are seldom of concern to the traditional “low-powered” devices such as microprocessors or CPUs for computers, especially micro- or personal computers. However, with the rapid advancement of microelectronics coupled with the rush by component manufacturers to complete by squeezing an ever increasing number of circuitries on a single IC chip, integrated circuits (IC), and particularly microprocessors or CPUs, become more and more highly integrated with separation between adjacent circuitries within a single IC chip becoming less and less. At the same time, microprocessor manufacturers are also racing to turn out microprocessors having very high operating clock rates. With the ultra high density of circuit integration together with the high operating clock rates the heat generated by a single microprocessor becomes an important issue.

Conventional heat sinks are either of the integral or the non-integral type. The non-integral type of heat sinks consists primarily of a number of discrete components, which are assembled together by, for instance welding, fastening or riveting to form a complete heat sink. Heat sinks of the integral type are usually formed and manufactured from a billet by either hot extrusion, forging, die casting, cutting or milling.

The U.S. Pat. No. 6,367,542 relates to a heat sink assembly with dual fans where the heat assembly includes a heat sink, an internal fan, a fan frame and an external fan. The heat sink itself includes a base and a fin member attached to the base. The fin member includes a central portion and a plurality of fins extending radially from the central portion. The fan frame has an opening defined therein and is mounted on the heat sink. The external fan is mounted on the fan frame such that it covers the opening. The internal fan accelerates airflow from upper portions of the fin member to lower portions of the fin member.

The U.S. patent application publication No. 2002/0024797 describes a heat dissipation device which comprises a chassis and a fin member. The chassis is formed as a single unit by extrusion and includes a top surface. The fin member is formed from a single plate and defines four parallel grooves and a channel therethrough. The channel is defined between the two innermost grooves, and is adapted to interferentially receive a conventional clip. The clip secures the heat dissipation device to a heat-generating electronic device. The four grooves interferentially receive the ribs of the chassis, thereby securely attaching the fin member to the chassis.

When thinking the heat sinks they have a design where much of the heat transfer area, metal-to-air is far away from the heat source, from the processor itself. The heat generated by the processor will, due to the heat resistance in the thin fins, only in small amounts reach the areas of the fins being at a long distance from the processor. Therefore, for instance the U.S. Pat. No. 6,367,542 uses an internal fan to accelerate airflow from upper portions of the fin member to lower portions of the fin member. However, this arrangement does not add the heat transfer area in the vicinity of the processor.

The object of the invention is to eliminate some drawbacks of the prior art and to achieve an improved cooling element to be used as a heat sink in cooling of a microprocessor which cooling element has separately a heat distribution area and a heat transfer area. The essential features of the invention are enlisted in the appended claims.

In accordance with invention the cooling element used as a heat sink for an electronic device, as a microprocessor, contains a base member, a base plate, attached in one side to the electronic device to be cooled by the cooling element and in other side providing separate members for distribution of heat and for supporting a fan creating airflow for heat transfer and at least one fin member installed in space between of two adjacent distribution members. The distribution members form the heat distribution area and the fin members form the heat conduction area for the cooling element. The fan makes the heat to flow around the cooling element.

The base member attached in one side to the electronic device is in one preferred embodiment of the invention at the thickest in that part attached to the electronic device and the base member comes more and more thinner when reaching its edge area on that side wherein the electronic device is attached. The other side of the base member opposite to that side wherein the microprocessor is attached has a flat surface. In another embodiment of the invention the base member may have an essentially even thickness for the area and thus the surfaces in both sides of the base member are flat. The thickness is then advantageously thinner than the thickest part of the base member in the embodiment where the thickness will be come thinner towards to the edge area. The total volume of the base member in both embodiments is then good for avoiding high heat resistance.

The distribution members are in the preferred embodiment of the invention installed on that side of the base member having the flat surface in the essentially vertical position close to the periphery of the base member. The size and shape of the distribution members are such that a cavity is defined in the centre part on the base plate. The distribution members are made of copper, aluminium or silver in order to have high heat conductivity. The material for the distribution member can also be copper alloy or aluminium alloy. The distribution members are mechanically connected to each other so that between two adjacent distribution members at least one fin member is installed. The fin member is advantageously made of a corrugated metal strip, like copper, aluminium or silver. The material for the fin member can also be copper alloy or aluminium alloy. The fin member is installed in each space between two adjacent distribution members so that the fin member has alternatively a mechanical contact with both the distribution members.

The cavity in the centre part between the distribution members is for the fan, which makes air in the vicinity of the distribution members as wells as in the vicinity of the fin members to flow and thus removes the heat becoming from the electronic device.

In one embodiment of the invention a combination of the distribution members and the fin members is separately assembled from the combination of the fan and the base member with the electronic device to be cooled mechanically connected to each other. For the cooling element of the invention these combinations are fitted together.

As mentioned the base member has a mechanical contact with the electronic device and has the total volume to avoid high heat resistance. Based on the same reason the distribution members are thicker than the fin members in order that heat can be conducted towards the members, which have smaller heat resistance than the previous members. The heat conducted into the fin members are then transferred by airflow created by means of the fan. Also one advantage in using thin fin members is that air pressure drop at forced cooling created by the fan will be lower and allows a higher air flow rate at the same fan power, thus also increasing the cooling capacity.

The invention is described in more details referring to the following drawings where

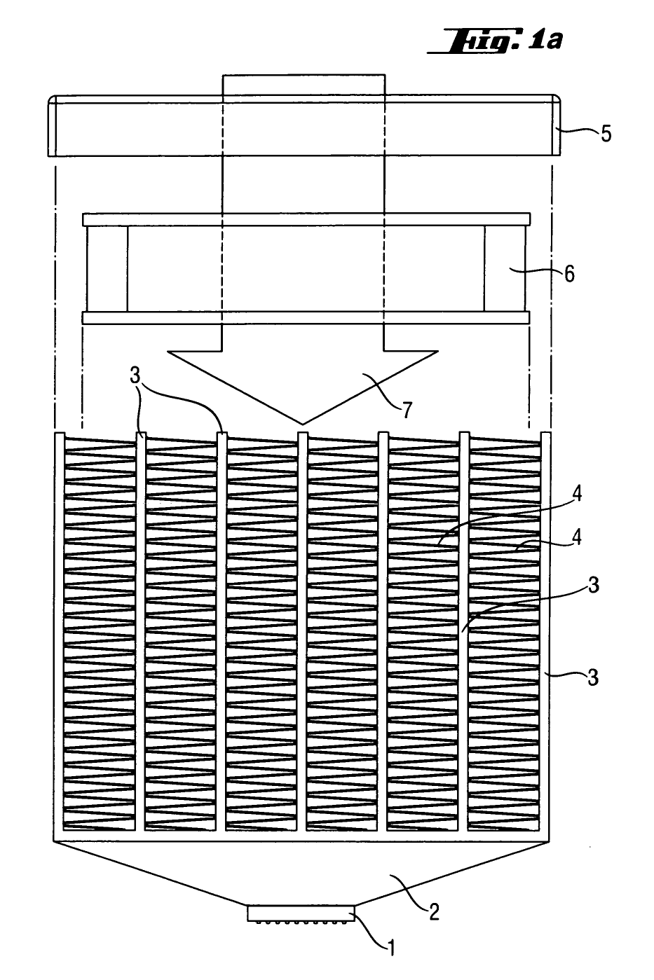

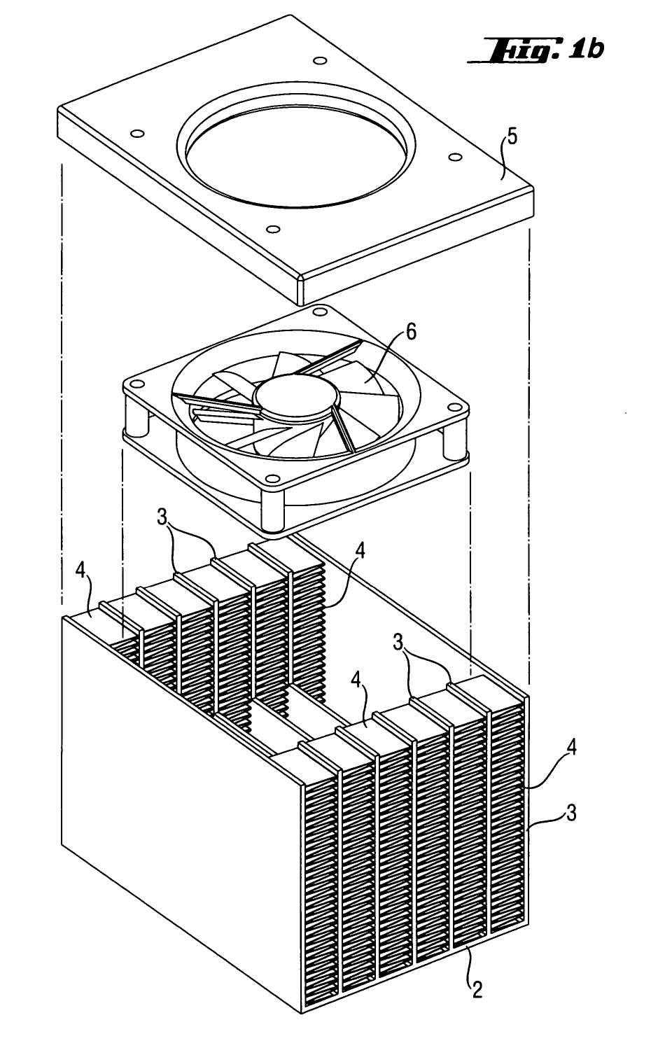

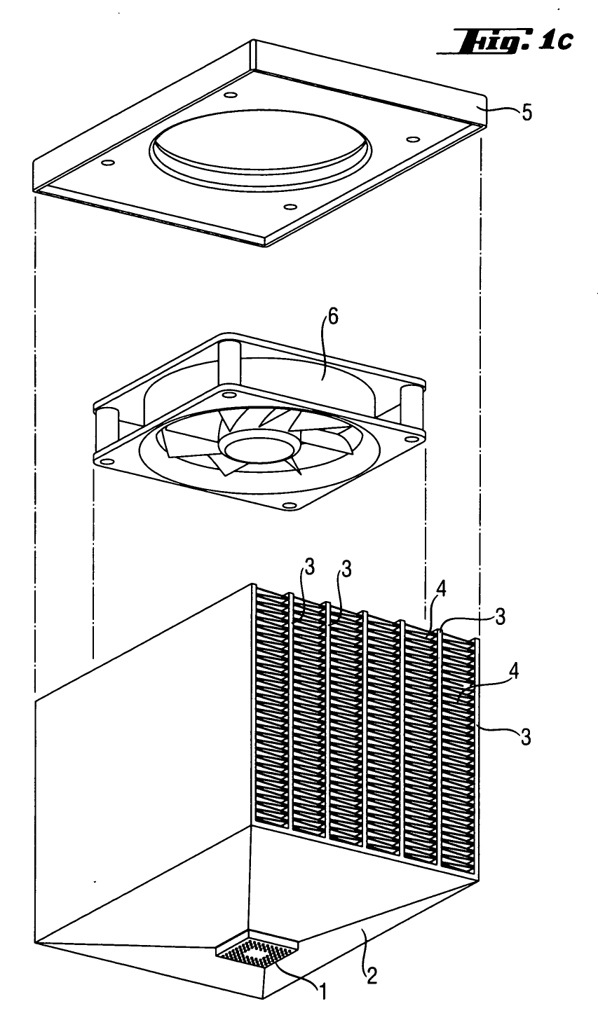

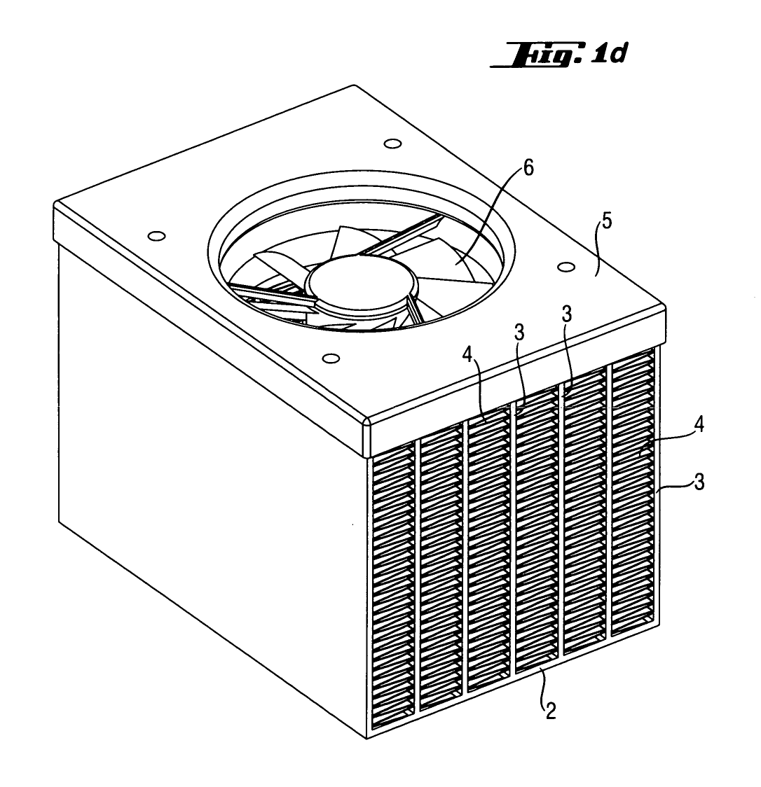

FIG. 1a illustrates a first embodiment of the invention as a view from one side,

FIG. 1b illustrates the embodiment of FIG. 1a as a perspective explosion view from one side, front side and above,

FIG. 1c illustrates the embodiment of FIG. 1a as a perspective explosion view from one side, front side and below,

FIG. 1d illustrates a perspective view of FIG. 1b in a built up configuration,

FIG. 1e illustrates a perspective view of FIG. 1c in a built up configuration,

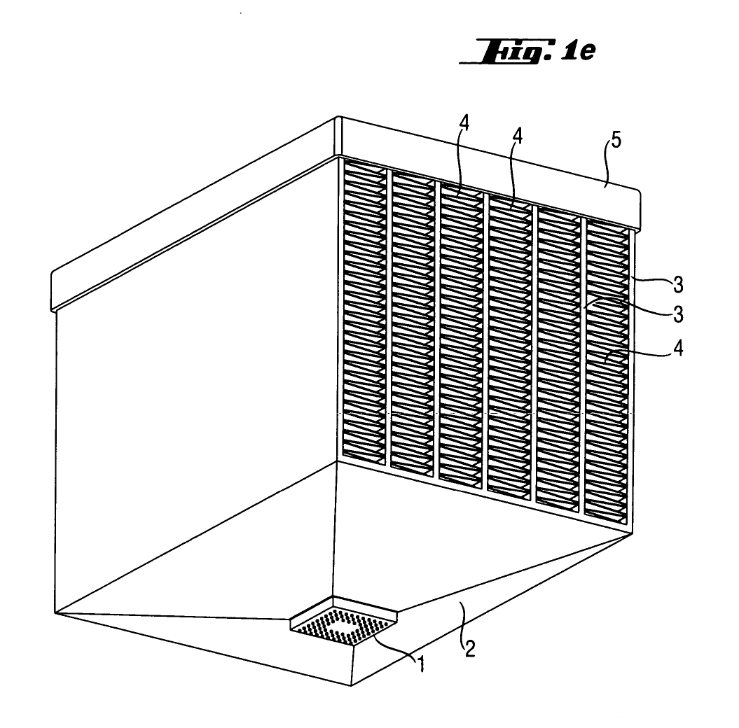

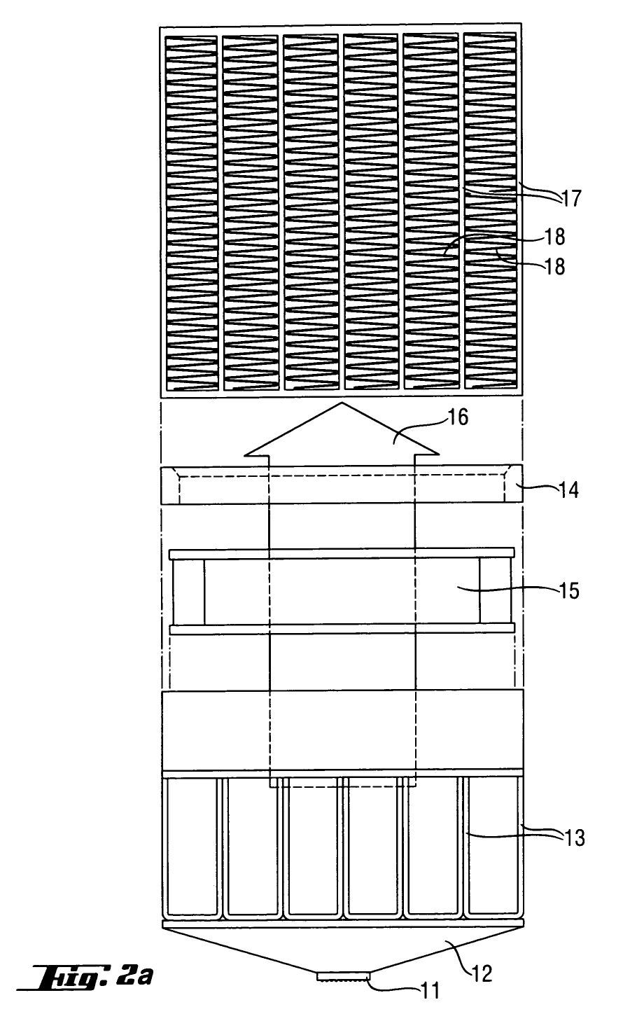

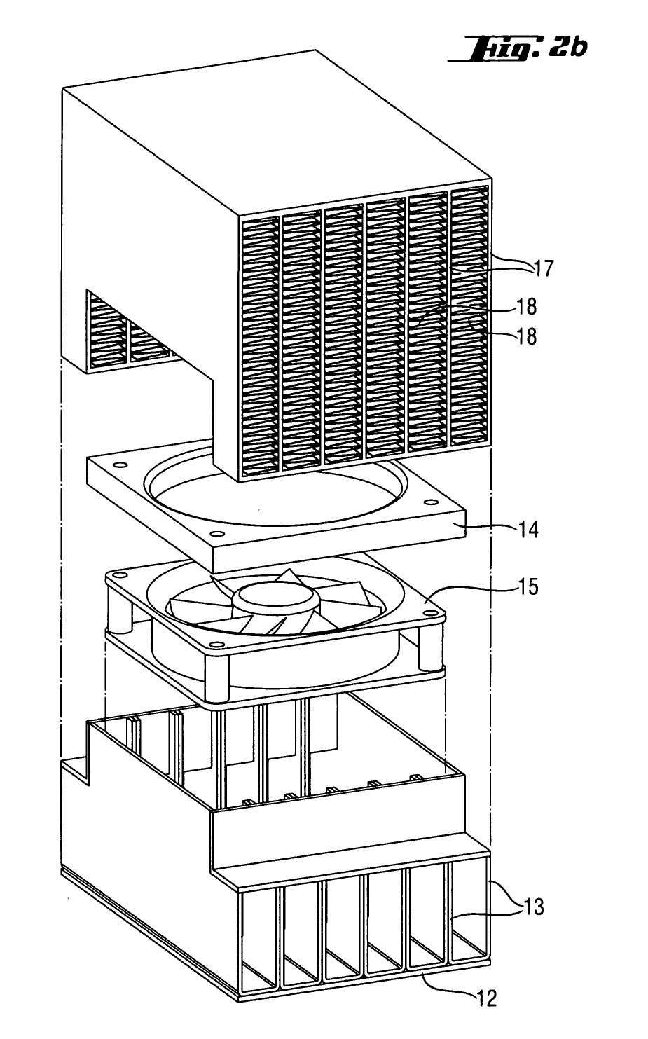

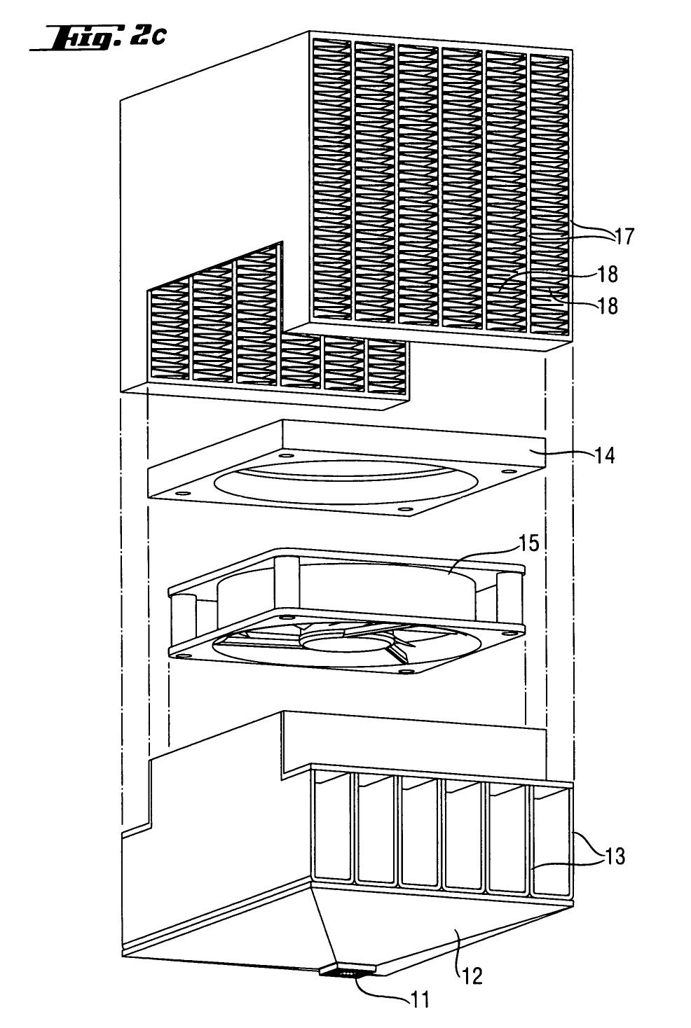

FIG. 2a illustrates a second embodiment of the invention as a view from one side,

FIG. 2b illustrates the embodiment of FIG. 2a as a perspective explosion view from one side, front side and above,

FIG. 2c illustrates the embodiment of FIG. 2a as a perspective explosion view from one side, front side and below,

FIG. 2d illustrates a perspective view of FIG. 2c in a built up configuration,

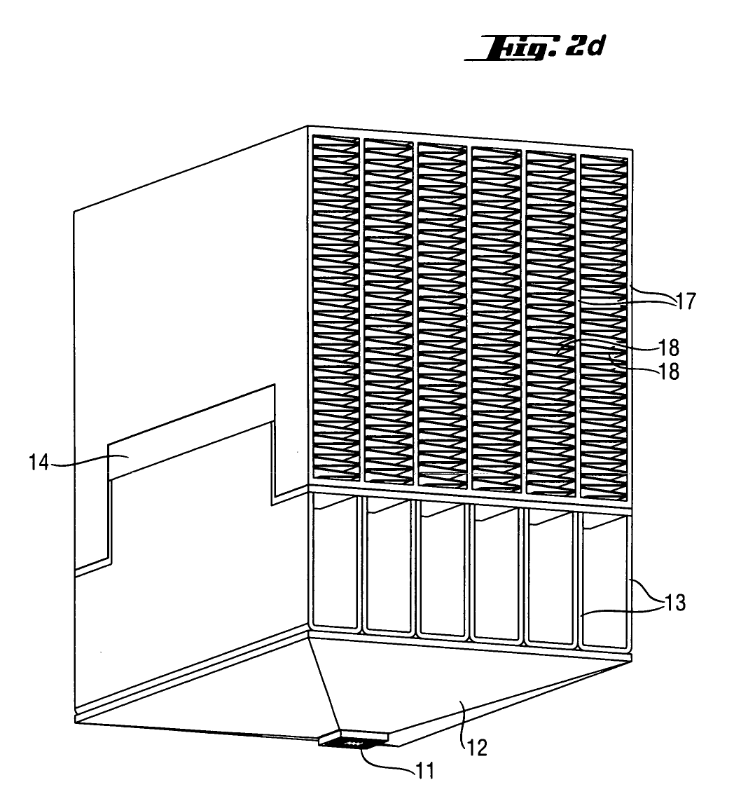

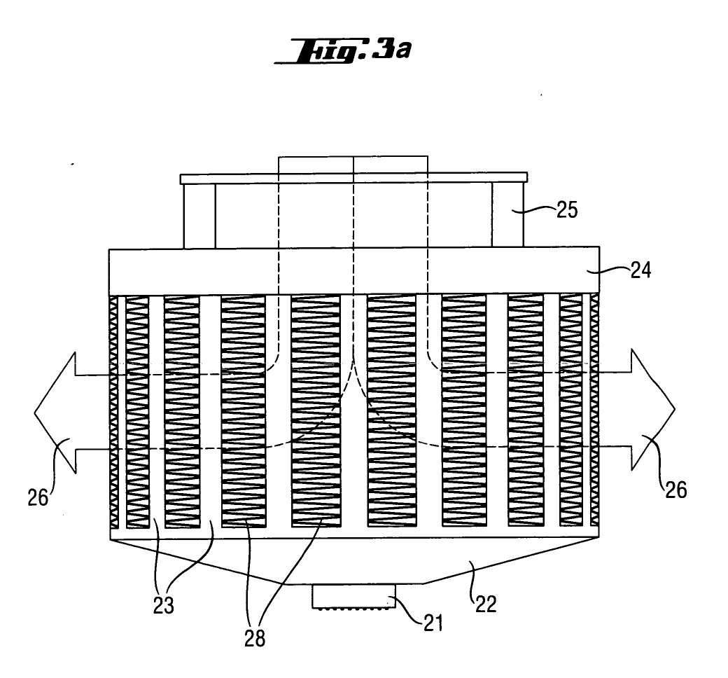

FIG. 3a illustrates a third embodiment of the invention as a view from one side,

FIG. 3b illustrates the embodiment of FIG. 3a as a perspective explosion view from one side, front side and above,

FIG. 3c illustrates the embodiment of FIG. 3a as a perspective view in a built up configuration from one side, front side and above,

FIG. 3d illustrates the embodiment of FIG. 3a as a perspective view in a built up configuration from one side, front side and below,

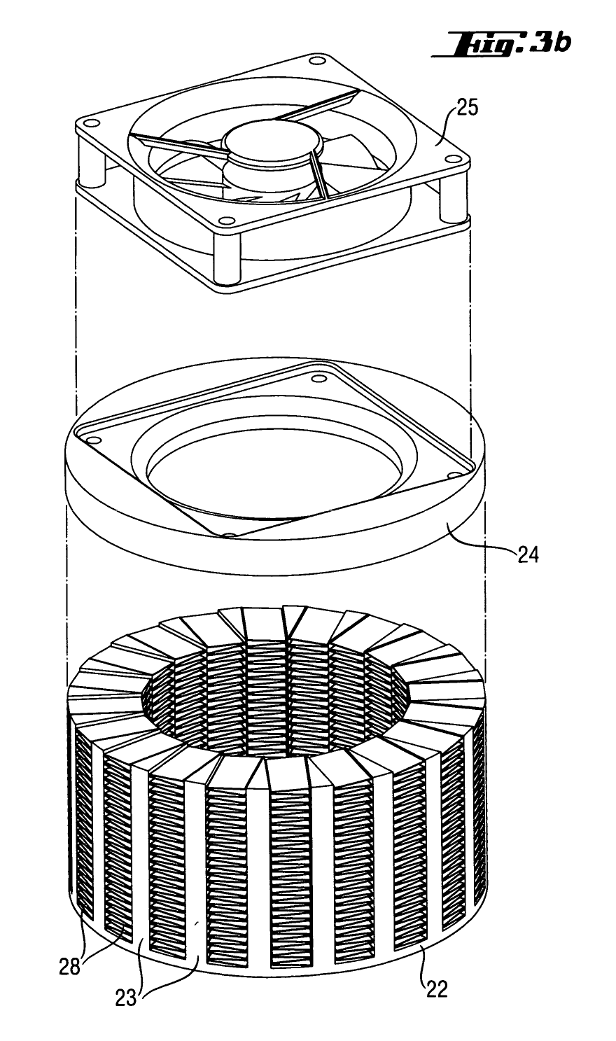

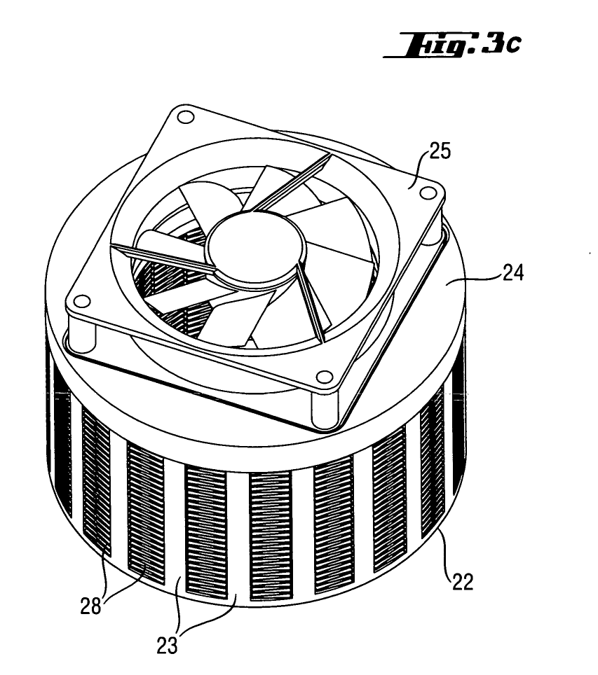

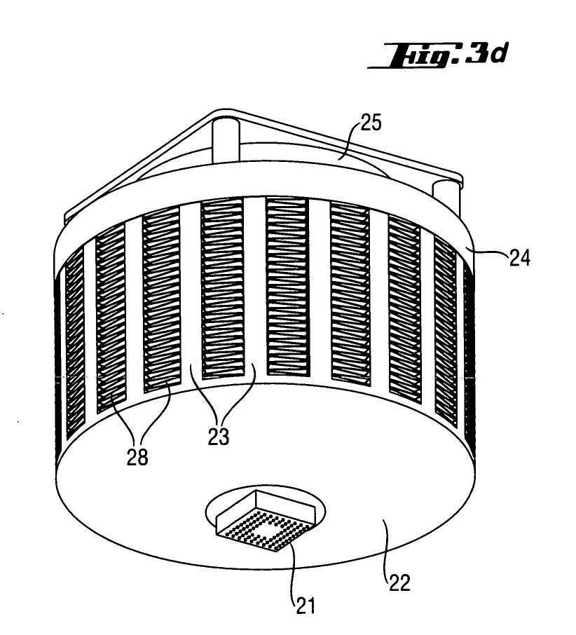

FIG. 4 illustrates the embodiment of FIG. 3a as a top view without a fan,

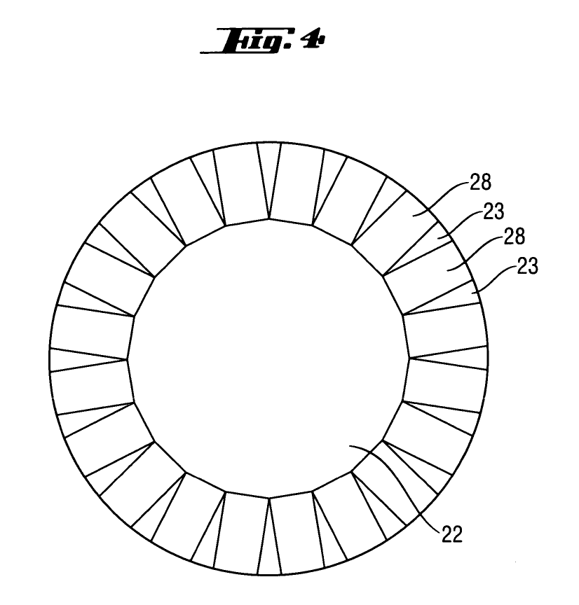

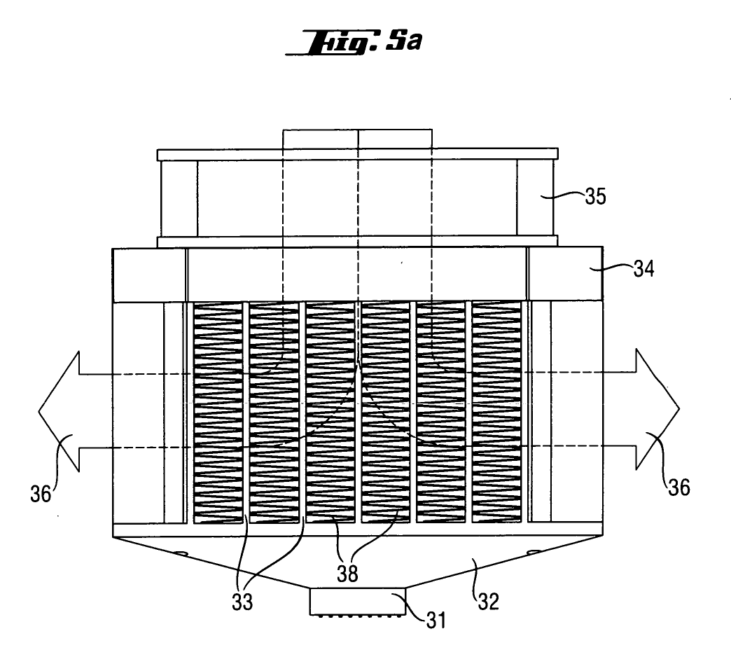

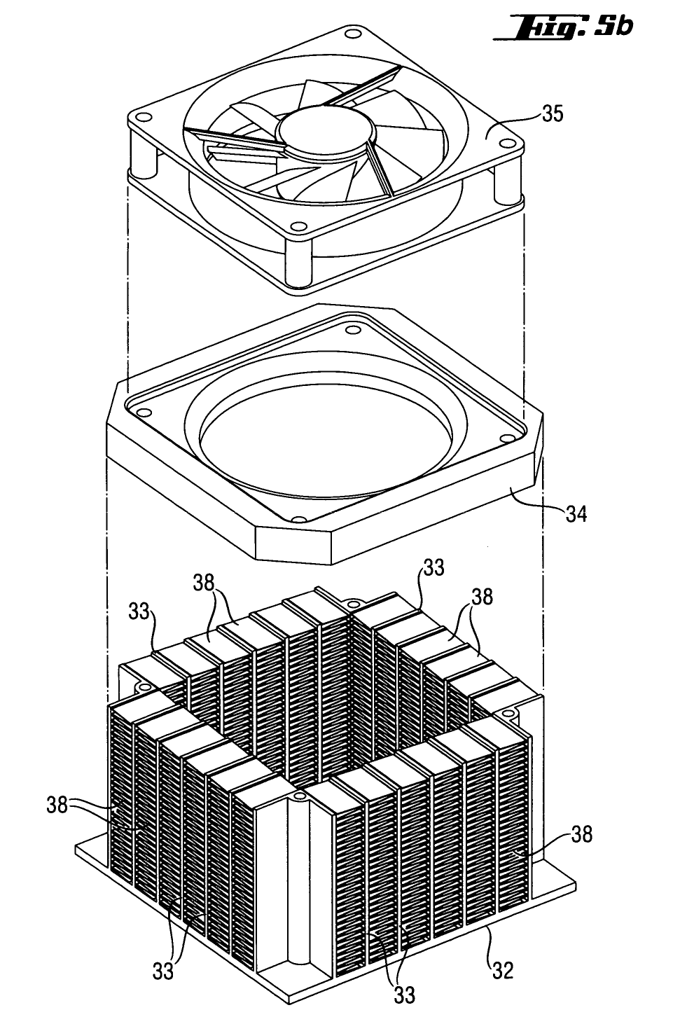

FIG. 5a illustrates a fourth embodiment of the invention as a view from one side,

FIG. 5b illustrates the embodiment of FIG. 5a as a perspective explosion view from one side, front side and above,

FIG. 5c illustrates the embodiment of FIG. 3a as a perspective view in a built up configuration from one side, front side and above,

FIG. 5d illustrates the embodiment of FIG. 3a as a perspective view in a built up configuration from one side, front side and below,

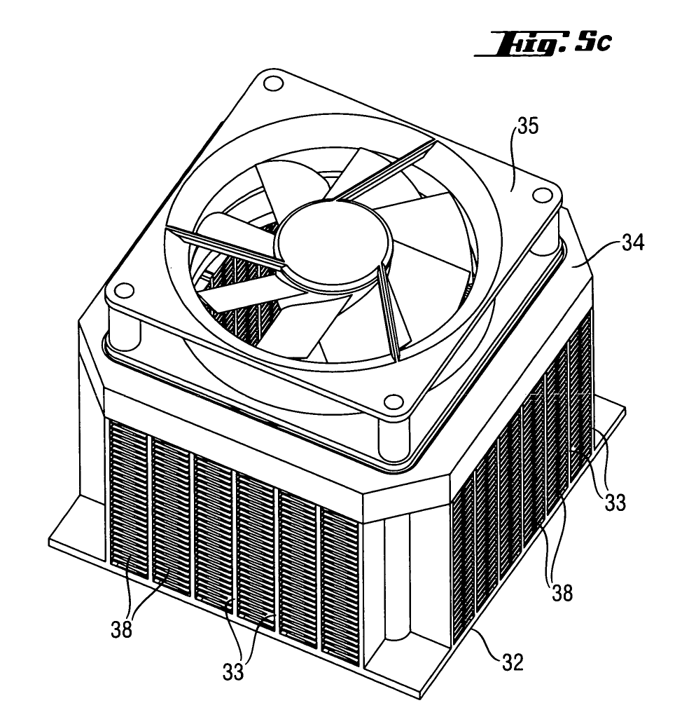

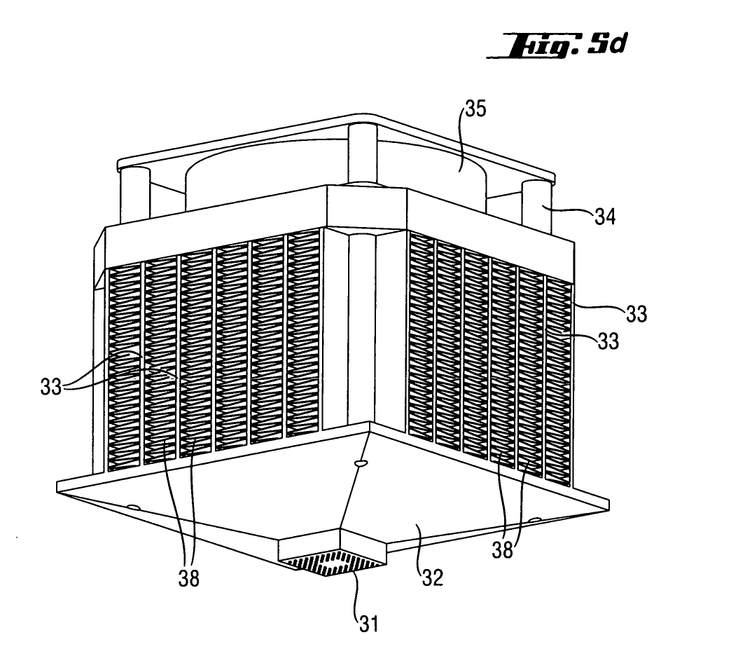

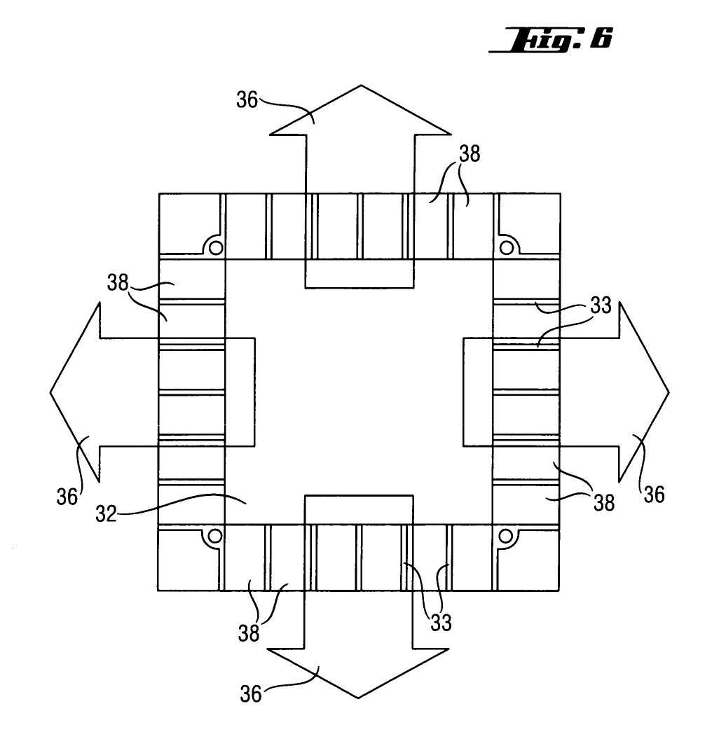

FIG. 6 illustrates the embodiment of FIG. 5a as a top view without a fan.

According to from FIG. 1a to FIG. 1e, a microprocessor 1 is attached to the centre part of a base plate 2 of the cooling element. The base plate 2 is at the thickest in that part attached to the microprocessor 1 and the base plate 2 comes more and more thinner when reaching the edge area of the base plate 2 on that side wherein the microprocessor 1 is attached. The other side opposite of the base plate 2 opposite to that side wherein the microprocessor 1 is attached has a flat surface. A plurality of distribution members 3 is installed on the periphery of the flat side of the base plate 2 in the essentially vertical position to the surface of the base plate 2. The adjacent distribution members 3 have a mechanical contact to each other by fin members 4. A fan frame 5 is installed on the distribution members 3 in that end which is opposite to the base plate 2 so that the fan 6 is positioned in a cavity formed in the middle of the distribution members 3. The arrow 7 shows the direction when the fan 6 and the base plate 2 with the microprocessor 1 and the distribution members 3 are assembled together.

In accordance with from FIG. 2a to FIG. 2d, a microprocessor 11 is attached to the centre part of a base plate 12 of the cooling element. The shape of the base plate 12 in the thickness is similar to the base plate 2 for the embodiment illustrated in the FIG. 1. A plurality of distribution members 13 is installed on the periphery of the flat side of the base plate 12 in the essentially vertical position to the surface of the base plate 12. A fan frame 14 is installed on the distribution members 13 in that end which is opposite to the base plate 12. The fan 15 itself is positioned in the cavity formed in the middle of the distribution members 13. The arrow 16 shows the direction when the fan 15 and the base plate 12 with the microprocessor 11 and the distribution members 13 are assembled together.

The heat transfer area of the embodiment illustrated in FIG. 2a-d is based on the external distribution members 17. Two adjacent external distribution members 17 have a mechanical contact to each other by fin members 18. The combination of the external distribution members 17 and the fin members 18 is installed to encircle the cooling element shaped by the distribution members 13 fitted to the base plate 12.

In the embodiment of the FIGS. 3a, 3b, 3c, 3d and FIG. 4 a microprocessor 21 is attached to the centre part of a circular base plate 22 of the cooling element. The shape of the base plate 22 in the thickness is similar to the base plate 2 for the embodiment illustrated in the FIG. 1a-e. A plurality of distribution members 23 is radially installed on the periphery of the flat side of the base plate 22 in the essentially vertical position to the surface of the base plate 22. A fan frame 24 is installed on the distribution members 23 in that end which is opposite to the base plate 22. The fan 25 is positioned in the cavity formed in the middle of the distribution members 23. The arrows 26 show the direction of airflow created by the fan 25. Two adjacent distribution members 23 have a mechanical contact to each other by fin members 28. The combination of the distribution members 23 and the fin members 28 is installed to encircle the cooling element shaped by the distribution members 23 fitted to the base plate 22.

In the embodiment of the FIGS. 5a, 5b, 5c, 5d and 6a microprocessor 31 is attached to the centre part of a quadratic base plate 32 of the cooling element. The shape of the base plate 32 in the thickness is similar to the base plate 2 for the embodiment illustrated in the FIG. 1a-e. A plurality of distribution members 33 is installed on the periphery of the flat side of the base plate 32 in the essentially vertical position to the surface of the base plate 32. A fan frame 34 is installed on the distribution members 33 in that end which is opposite to the base plate 32. The fan 35 is positioned in the cavity formed in the middle of the distribution members 33. The arrows 36 show the direction of airflow created by the fan 35. The heat transfer area is based on the distribution members 33. Two adjacent distribution members 33 have a mechanical contact to each other by fin members 38. The combination of the distribution members 33 and the fin members 38 is installed to encircle the cooling element shaped by the distribution members 33 fitted to the base plate 32. In the corners of the base plate 32 two adjacent distribution members 33 are connected to each other by the fin members 38 so that the contact is essentially only in one point.

While the invention has described with respect to certain specific embodiments, it will be appreciated that many modifications and changes may be made by those skilled in the art without departing from the spirit of the invention. It is intended, therefore, by the appended claims to cover all such modifications and changes as fall within the true spirit and scope of the invention.

1. A cooling element to be used as a heat sink for an electronic device the cooling element comprising a base member one side of which is attached to the electronic device and the other side of which having separate members for distribution of heat and for supporting a fan installed in a cavity in the middle of members for distribution, an element creating airflow for heat transfer, at least one fin member being installed in the space between two adjacent distribution members and the combination of the distribution members and the fin members being installed to encircle the cooling element shaped by the distribution members fitted to the base plate.

2. A cooling element of claim 1, wherein the fin member has alternatively a mechanical contact with the adjacent distribution members.

3. A cooling element of claim 1, wherein the fin member is made of a corrugated strip.

4. A cooling element of claim 1, wherein the distribution members and the fin members are made of the same material.

5. A cooling element of claim 1, wherein the distribution members and the fin members are made of different material.

6. A cooling element of the material for the distribution members and the fin members are selected from the group consisting of copper, aluminum and silver.

7. A cooling element of claim 1, wherein the material for the distribution members and the fin members are selected from the group consisting of copper alloys and aluminum alloys.
